(19) United States
(12) Patent Application Publication
(10) Pub. No.: US 2019/0393254 A1
(43) Pub. Date: Dec. 26, 2019

(54) ENCAPSULATION STRUCTURE FOR IMAGE SENSOR CHIP AND METHOD FOR MANUFACTURING THE SAME

(71) Applicant: TRIPLE WIN TECHNOLOGY(SHENZHEN) CO.LTD., Shenzhen (CN)

(72) Inventors: CHIA-WEI CHEN, New Taipei (TW); SHIN-WEN CHEN, New Taipei (TW); DING-NAN HUANG, New Taipei (TW)

(21) Appl. No.: 16/201,916

(22) Filed: Nov. 27, 2018

(30) Foreign Application Priority Data
Jun. 26, 2018 (CN) 201810669982.1

(51) Int. Cl. H01L 27/146

(52) U.S. Cl. CPC H01L 27/14618; H01L 27/14685; H01L 27/14627; H01L 27/14623

(57) ABSTRACT

An encapsulation structure to protect an image sensor chip at all times includes a printed circuit board, an image sensor chip, a protecting structure, and a package portion. The image sensor chip is mounted on the printed circuit board and the protecting structure is mounted on the image sensor chip. The protecting structure comprises a filter sheet. The package portion is entirely opaque and is formed on the printed circuit board, wrapping side wall of the printed circuit board, side wall of the protecting structure, and a portion of surface of the filter sheet which is away from the image sensor chip.

### FIELD

The subject matter herein generally relates to packaging of components.

### BACKGROUND

A chip encapsulation structure includes a printed circuit board and an image sensor chip mounted on the printed circuit board. Before the chip encapsulation structure is assembled to a lens module, it is exposed to the air for some time, and the image sensor chip can be polluted because of dust and fragments.

Therefore, there is room for improvement within the art.

### BRIEF DESCRIPTION OF THE DRAWINGS

Implementations of the present technology will now be described, by way of example only, with reference to the attached figures.

FIG. 1 is a flowchart of a manufacturing method for the chip encapsulation structure in FIG. 9.

FIG. 2 is a cross-sectional view of a printed circuit board.

FIG. 3 is a cross-sectional view of an image sensor chip formed on the printed circuit board in FIG. 2.

FIG. 4 is a cross-sectional view of the image sensor chip and the printed circuit board in FIG. 3 electrically connected.

FIG. 5 is a cross-sectional of a protecting structure formed on the image sensor chip in FIG. 4.

FIG. 6 is an isometric view of the protecting structure in FIG. 5 and the printed circuit board in FIG. 2.

FIG. 7 is a cross-sectional of a removable retaining wall formed and glued on the protecting structure in FIG. 5.

FIG. 8 is a cross-sectional of a package portion formed on the printed circuit board in FIG. 7.

FIG. 9 is a cross-sectional of FIG. 8 with the removable glue layering being removed.

FIG. 10 is an isometric view of the chip encapsulation structure in FIG. 9 in accordance with one embodiment.

FIG. 11 is a cross-sectional view of the chip encapsulation structure formed as a camera device.

FIG. 12 is an isometric view of a chip encapsulation structure in accordance with one embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better. The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. The references “a plurality of” and “a number of” mean “at least two.”

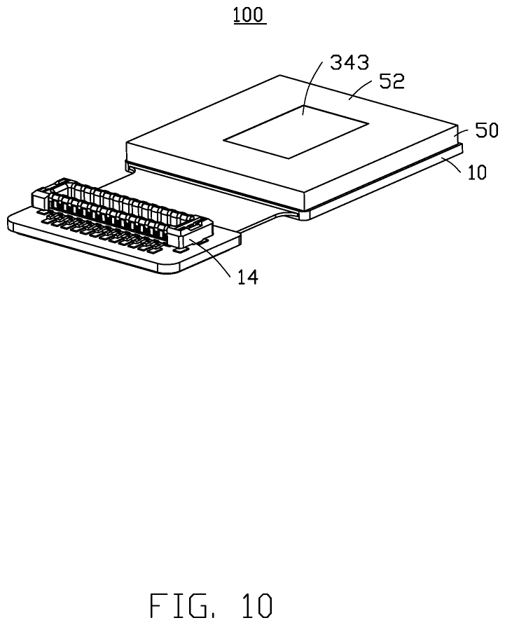

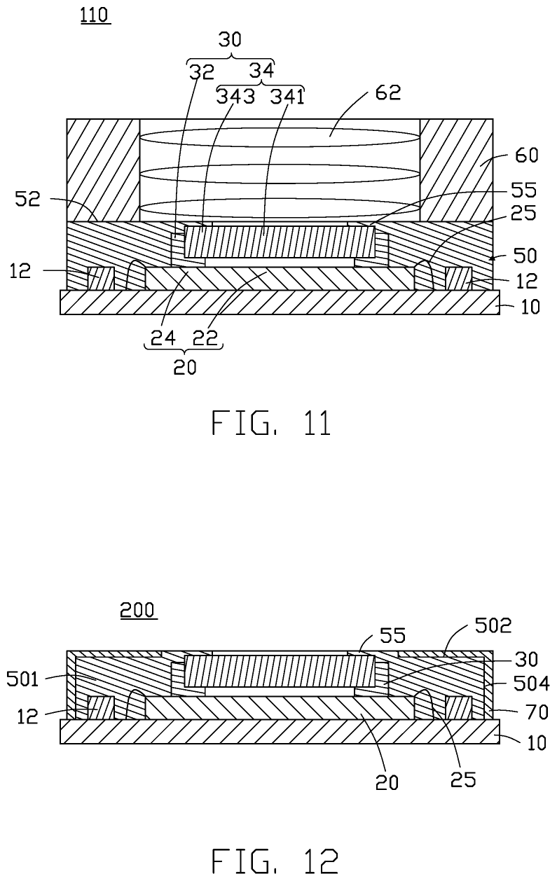

FIGS. 9-10 illustrate a chip encapsulation structure 100 used in an imaging device, according to one embodiment of the present application. The chip encapsulation structure 100 includes a printed circuit board 10, an image sensor chip 20, a protecting structure 30, and a package portion 50.

The printed circuit board 10 can be a flexible circuit board or a rigid-flexible board. In the illustrated embodiment, the printed circuit board 10 is a ceramic board.

The printed circuit board 10 is provided with a plurality of circuit components 12 and a connector 14. In this embodiment, the circuit elements 12 are mounted on an edge area of the printed circuit board 10. The circuit elements 12 are electrically connected to the image sensor chip 20. The circuit elements 12 may be, but are not limited to, resistors, capacitors, diodes, transistors, potentiometers, relays or drivers, etc. The connector 14 is electrically connected to the image sensor chip 20 for signal transmission between the image sensor chip 20 and an electronic device.

The image sensor chip 20 is mounted on a central area of the printed circuit board 10 and electrically connected to the printed circuit board 10 via the wires 25.

The image sensor chip 20 includes a photosensitive area 22 surrounded by a non-photosensitive area 24.

The protecting structure 30 includes a supporting frame 32 and a filter sheet 34 mounted with the supporting frame 32. The supporting frame 32 includes an aperture 320 and the aperture 320 exposes a portion of the filter sheet 34. The protecting structure 30 is fixed on the non-photosensitive area 24 of the image sensor chip 20, and the supporting frame 32 exposes the photosensitive area 22 to allow light to incident thereon. The protecting structure 30 is configured to protect the image sensor chip 20, and avoid dust and fragments from falling on the image sensor chip 20.

In the embodiment, the supporting frame 32 includes a step portion 36.

The step portion 36 includes a bearing surface 322, the bearing surface 322 is substantially L shaped. and the filter sheet 34 is fixed on the bearing surface 322. In other embodiment, the filter sheet 34 is directly fixed on the aperture 320. The filter sheet 34 defines a light transmission area 341 and a peripheral area 343 surrounding the light transmission area 341 along an optical path direction of a lens module. The light transmission area 341 corresponds to the photosensitive area position 22.

The package portion 50 has complete opacity. The package portion 50 is mounted on the printed circuit board 10 and wraps the side wall of the printed circuit board 10, side wall of the supporting frame 32, and the peripheral area 343 of the filter sheet 34. A material of the package portion 50 is plastic or resin, and color of the package portion 50 is black or dark color. The package portion 50 locating on the peripheral area 343 forms a light shielding layer 55. A thickness of the light shielding layer 55 is in a range from 0.1 millimeters to 0.3 millimeters.

When the chip encapsulation structure 100 is assembled with a lens module 60 to form a camera device 110, the light shielding layer 55 absorbs stray light, preventing ghosting.

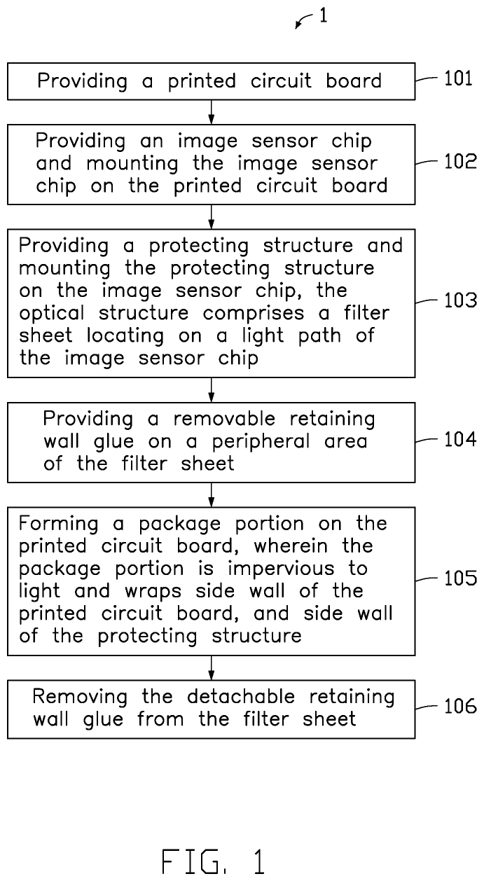

FIG. 1 illustrates a method for manufacturing an image sensor chip encapsulation structure according to one embodiment of the present application. The method 1 is provided by way of example as there are a variety of ways to carry out the method. The method 1 can begin at block 101.

At block 101, a printed circuit board 10 as shown in FIG. 2 is provided.

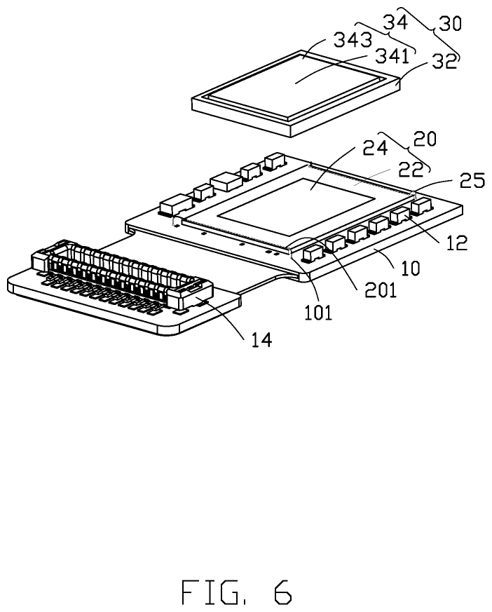

The printed circuit board 10 is provided with circuit members 12 and a connector 14, as shown in FIG. 6. The printed circuit board 10 can be selected from, but is not limited to, a flexible circuit board or a rigid-flexible board, ceramic substrates, etc. In this embodiment, the circuit elements 12 are mounted at an edge area of the printed circuit board 10. The circuit elements 12 are electrically connected to the image sensor chip 20 for the photosensitive working process of the photosensitive chip 20. The circuit elements 12 may be, but are not limited to, resistors, capacitors, diodes, transistors, potentiometers, relays, and drivers. The electric connector 14 is electrically connected to the image sensor chip 20 to realize the signal transmission between the image sensor chip 20 and an electronic device.

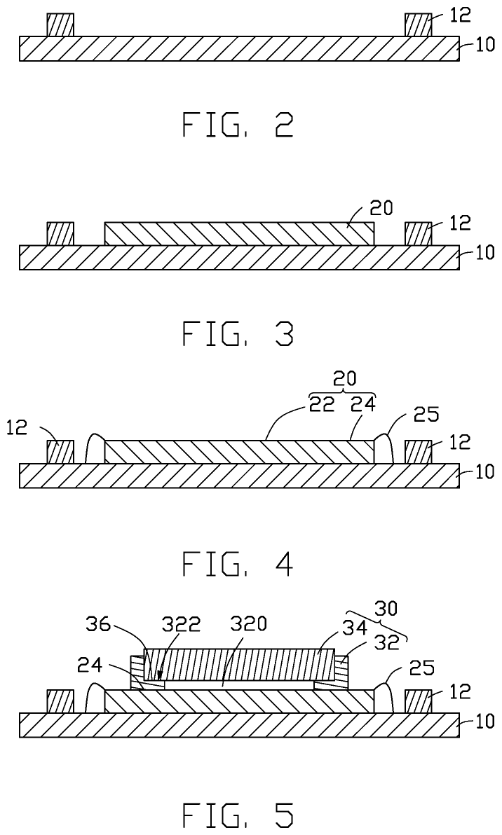

At block 102, the image sensor chip 20 as shown in FIG. 3 is provided, and the image sensor chip 20 is mounted on the printed circuit board 10 and electrically connected to the printed circuit board 10. The image sensor chip 20 includes a photosensitive area 22 and a surrounding non-photosensitive area 24.

In the embodiment, the image sensor chip 20 is mounted on a central area of the printed circuit board 10 a via a flip-chip method. As shown in FIG. 6, a plurality of conductive pads 101, 201 are provided on the printed circuit board 10 and the image sensor chip 20. Wires 25 are applied to electrically connect the image sensor chip 20 and the printed circuit board 10, as shown in FIG. 4. The wires 25 connect to the conductive pads 101, 201 provided on the printed circuit board 10 and the image sensor chip 20. Wires 25 may be selected from, but are not limited to, gold, copper, aluminium, silver, etc. In particular, the wires 25 are arced or bent, thereby avoiding bending damage to the wires 25.

At block 103, as shown in FIG. 5 and FIG. 6, a protecting structure 30 is provided and fixed on the non-photosensitive area 24 of the image sensor chip 20. In the embodiment, a protective cover 30 is mounted on the image sensor chip 20 when the image sensor chip 20 and the printed circuit board 10 are first connected, to reduce an exposure time of the image sensor chip 20 to the air. The protecting structure 30 is configured to protect the image sensor chip 20, to avoid dust and fragments from falling on the photosensitive area 22 of the image sensor chip 20.

The protecting structure 30 includes a supporting frame 32 and a filter sheet 34 mounted with the supporting frame 32. When the protecting structure 30 is fixed on the image sensor chip 20, the supporting frame 32 is located on the non-photosensitive area 24. The supporting frame 32 includes an aperture 320 to provide a light path for the image sensor chip 20. The aperture 320 exposes the photosensitive area 22.

The supporting frame 32 includes a step portion 36, the step portion 36 includes a bearing surface 322, and the filter sheet 34 is fixed on the bearing surface 322. The filter sheet 34 defines a light transmission area 341 and a peripheral area 343 surrounding the light transmission area 341 along the optical path. The light transmission area 341 corresponds to the photosensitive area position 22.

In the embodiment, the filter sheet 34 is an infrared cut-off filter used to filter out infrared portion of light. The filter sheet 34 may also be a color filter.

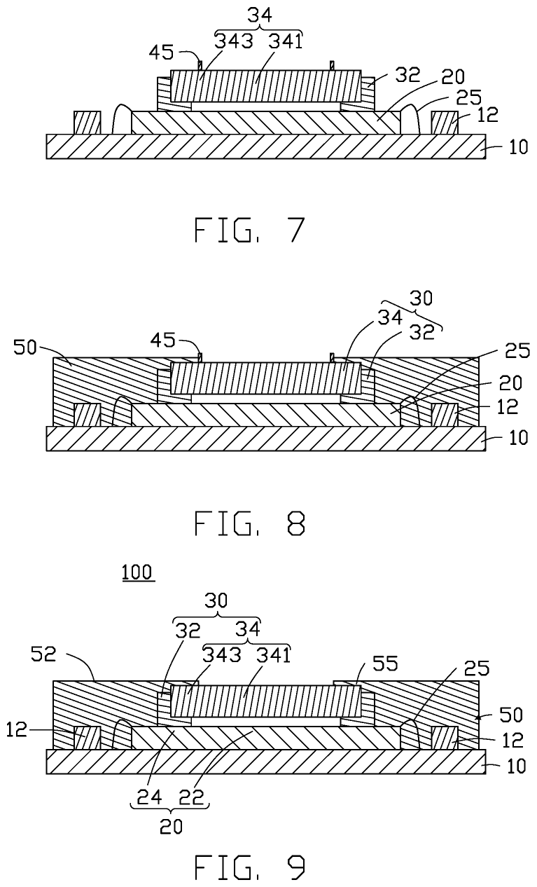

At block 104, as shown in FIG. 7, a removable glue layer 45 is provided on a peripheral area 343 of the filter sheet 34 as a retaining wall. The removable glue layer 45 protects the light transmission area 341 when forming the package portion 50 in the next step, to prevent molding material from entering the light transmission area 341 while molding.

At block 105, as shown in FIG. 8, the package portion 50 is formed on the printed circuit board 10. The package portion 50 also packages the circuit elements 12 and the wires 25 in its interior so that the circuit elements 12 are not directly exposed to air. The package portion 50 has complete opacity. The package portion 50 wraps the side wall of the image sensor chip 20, the side wall of the supporting frame 32, and the peripheral area 343 of the protection glass 34. A color of the package portion 50 is black or dark color. The package portion 50 on the peripheral area 343 forms a light shielding layer 55.

The molding material is applied on the peripheral area 343 of the filter sheet by flowing, thus thickness of the light shielding layer 55 is controllable. In the embodiment, a thickness of the light shielding layer 55 is in a range from 0.1 millimeters to 0.3 millimeters. The light shielding layer 55 absorbs stray light.

The light shielding layer 55 is formed during the process of molding on chip (MOC). In this way, there is no need to apply a black paint on the peripheral area 343 of the filter sheet 34 to absorb stray light. A production costs of the protective glass 34 is reduced. The package portion 50 may be formed by, but is not limited to, an injection molding process or a molding process. The package portion 50 can be selected from but is not limited to nylon, LCP (liquid crystal polymer), PP (Polypropylene, polypropylene), or resin.

At block 106, as shown in FIG. 9, the detachable retaining wall glue 45 is removed to obtain the chip encapsulation structure 100.

The packaging portion 50 includes a supporting surface 52 away from the printed circuit board 10, the support surface 52 is flat. When the chip encapsulation structure 100 is used to form a camera device 110 as shown in FIG. 10, a lens module 60 is fixed on the supporting surface 52 of the package portion 50. The optical lens 60 includes at least one lens 62. Close proximity between the at least one lens 62 and the filter sheet 34 can lead to optical interference and the at least one lens 62 can be physically ruptured. In the embodiment, due to the light shielding layer 55, the distance between the at least one lens 62 and the filter sheet 34 is increased, interference between the at least one lens 62 and the filter sheet 34 is reduced.

FIG. 12 shows a chip encapsulation structure 200 according to another embodiment. The chip encapsulation structure in FIG. 12 is similar to chip encapsulation structure 100 in FIG. 9. The difference between the chip encapsulation structure 200 and the chip encapsulation structure 100 in FIG. 9 is that the package portion 501 includes a supporting surface 502 away from the printed circuit board 10 and a side surface 504 perpendicular to the supporting surface 502. The package portion 501 further includes a metal sheet 70, the metal sheet is insert molded on the supporting surface 502 and the side surface 504, the metal sheet 70 increases a strength of the packaging portion 501.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A chip encapsulation structure comprising:
a printed circuit board;
an image sensor chip mounted on the printed circuit board; and
a protecting structure mounted on the image sensor chip, the optical structure comprises a filter sheet locating on a light path of the image sensor chip; and
a package portion formed on the printed circuit board, wherein the package portion has complete opacity and wraps side wall of the printed circuit board, and side wall of the protecting structure.

2. The chip encapsulation structure of claim 1, wherein:
the package portion further covers a portion surface of the filter sheet away from the image sensor chip, and the package portion locating on the portion surface of the filter sheet forms a light shielding layer.

3. The chip encapsulation structure of claim 1, wherein:
the protecting structure further comprises a supporting frame, the supporting frame comprises an aperture, the filter sheet is mounted with the supporting frame and the aperture exposes portion of the filter sheet.

4. The chip encapsulation structure of claim 3, wherein:
the supporting frame comprises a step portion, the step portion comprises a bearing surface, the bearing surface is substantially L shaped, and the filter sheet is fixed on the bearing surface.

5. The chip encapsulation structure of claim 2, wherein:
the filter sheet defines a light transmission area and a peripheral area surrounding the light transmission area, the light transmission area corresponds to the photosensitive area, and the light shielding layer is formed on the peripheral area.

6. The chip encapsulation structure of claim 5, wherein:
a thickness of the light shielding layer is in a range from 0.1 millimeters to 0.3 millimeters.

7. The chip encapsulation structure of claim 6, wherein:
the image sensor chip comprises a photosensitive area and a non-photosensitive area surrounding the photosensitive area, and the protecting structure is fixed on the non-photosensitive area.

8. The chip encapsulation structure of claim 1, wherein:
the packaging portion comprises a supporting surface away from the printed circuit board, and the support surface is flat.

9. The chip encapsulation structure of claim 8, wherein:
the package portion further comprises a metal sheet, the metal sheet is substantially L-shaped, and the metal sheet insert molding on the supporting surface and a side surface perpendicularly to the supporting surface.

10. A method for manufacturing a chip encapsulation structure comprising:
providing a printed circuit board;
providing an image sensor chip and mounting the image sensor chip on the printed circuit board;
providing a protecting structure and mounting the protecting structure on the image sensor chip, the optical structure comprises a filter sheet locating on a light path of the image sensor chip; and
forming a package portion on the printed circuit board, wherein the package portion is impervious to light and wraps side wall of the image sensor chip, and side wall of the protecting structure.

11. The method of claim 10, wherein
before the step of forming a package portion on the printed circuit board further comprises a step of providing a removable glue layer on a peripheral area of the filter sheet and after the step of forming the package portion, removing the detachable retaining wall glue from the filter sheet.

12. The method of claim 10, wherein
the image sensor chip comprises a photosensitive area and a non-photosensitive area surrounding the photosensitive area, and the protecting structure is fixed on the non-photosensitive area.

13. The method of claim 12, wherein:
the protecting structure further comprises a supporting frame, the supporting frame comprises an aperture, the filter sheet is mounted with the supporting frame and the aperture exposes portion of the filter sheet.

14. The method of claim 13, wherein:
the supporting frame comprises a step portion, the step portion comprises a bearing surface, the bearing surface is substantially L shaped, and the filter sheet is fixed on the bearing surface.

15. The method of claim 4, wherein:
the package portion further covers a portion surface of the filter sheet away from the image sensor chip, and the package portion locating on the portion surface of the filter sheet forms a light shielding layer.

16. The method of claim 15, wherein:
a thickness of the light shielding layer is in a range from 0.1 millimeters to 0.3 millimeters.
